(19) United States
(12) Patent Application Publication
(10) Pub. No.: US 2023/0054881 A1
(43) Pub. Date: Feb. 23, 2023

(54) Solid-State Quantum Memory

(71) Applicant: Nippon Telegraph and Telephone Corporation, Tokyo (JP)

(72) Inventors: Ryuichi Ota, Tokyo (JP); Takehiko Tawara, Tokyo (JP); Hajime Okamoto, Tokyo (JP); Hiroshi Yamaguchi, Tokyo (JP)

(21) Appl. No.: 17/799,560

(22) PCT Filed: Mar. 9, 2020
(86) PCT No.: PCT/JP2020/009939

§ 371 Date: Aug. 12, 2022

(51) Int. Cl. H01L 41/09; G06N 10/40; H01L 41/047; H01L 41/053; H01L 41/04; H01L 41/39

(52) U.S. Cl. CPC H01L 41/094; G06N 10/40; H01L 41/047; H01L 41/053; H01L 41/042; H01L 41/39

(57) ABSTRACT

A solid-state quantum memory includes a vibrator supported in a displaceable (vibratable) manner on a substrate and a vibration exciter configured to excite the vibrator to vibrate. A rare-earth element is introduced into the vibrator and the introduced rare-earth element forms an electronic two-level system in the vibrator. The vibrator is supported on the substrate by a support. The substrate including a piezoelectric element formed from a piezoelectric material, as well as a first electrode and a second electrode formed by sandwiching the piezoelectric element, serves as the vibration exciter.

### CROSS-REFERENCE TO RELATED APPLICATIONS

This patent application is a national phase filing under section 371 of PCT application no. PCT/JP2020/009939, filed on Mar. 9, 2020, which application is hereby incorporated herein by reference in its entirety.

### TECHNICAL FIELD

The present disclosure relates to a solid-state quantum memory which is a memory formed from an electronic two-level system introduced into a vibrator.

### BACKGROUND

Electronic two-level systems formed from impurities in semiconductors or solids can preserve quantum states of light as quantum states of electrons by utilizing light absorption and emission characteristics of the electronic two-level systems. In particular, solid materials containing erbium (Er), which is a rare-earth element, have an electronic level resonant to the telecom-wavelength band and have extremely long preservation time (coherence) of quantum state at the electronic level, and thus application as a quantum memory is expected (NPL 1).

Here, Er becomes an ion with an energy level having Kramers degeneracy. This type of element has an electronic level that is energy degenerated in the absence of a magnetic field, and a large energy change greater than inhomogeneous broadening of the electronic level needs to be given to obtain a long coherence.

For Er, to date, it has been reported that applying an external magnetic field of 7 T enables energy control of 1 GHz or higher in hyperfine structure that arises due to electron-nuclear spin coupling and long coherence of over a second has been achieved in an electron spin of Er (NPL 2). Energy control of an electronic level with an external magnetic field has been used to perform control of an electron with microwave (NPL 3).

### CITATION LIST

### Non Patent Literature

NPL 1: E. Saglamyurek et al., “Quantum storage of entangled telecom-wavelength photons in an erbium-doped optical fibre”, Nature Photonics, vol. 9, pp. 83-87, 2015.
NPL 2: M. Rancic et al., “Coherence time of over a second in a telecom-compatible quantum memory storage material”, Nature Physics, vol. 14, pp. 50-54, 2018.
NPL 3: J. R. Everts et al., “Microwave to optical photon conversion via fully concentrated rare-earth-ion crystals”, Physical Review A, vol. 99, no. 6, 063830, 2019.

### SUMMARY

### Technical Problem

As described above, in the related art, an external magnetic field has been used to control preservation of quantum state in the electronic level in order to implement a quantum memory. In order to generate the external magnetic field, a large superconducting coil is used, and thus reduction in size and power consumption of the overall system to implement a quantum memory has been difficult.

Embodiments of the present disclosure can solve the above problems, and an embodiment of the present disclosure reduces size and power consumption of the overall system to implement a quantum memory.

### Means for Solving the Problem

A solid-state quantum memory according to embodiments of the present disclosure includes a vibrator supported in a displaceable manner on a substrate, a vibration exciter that excites the vibrator to vibrate, and an electronic two-level system formed from a rare-earth element introduced into the vibrator.

### Effects of Embodiments of the Invention

As described above, according to embodiments of the present disclosure, an electronic two-level system is formed from a rare-earth element introduced into a vibrator, and thus reduction in size and power consumption of the overall system to implement a quantum memory can be achieved.

### BRIEF DESCRIPTION OF THE DRAWINGS

FIG. 1 is a perspective view illustrating a configuration of a solid-state quantum memory according to an embodiment of the present disclosure.

FIG. 2A is a characteristic diagram illustrating a resonance characteristic of a vibrator in a secondary vibration mode.

FIG. 2B is a distribution diagram illustrating distribution of strain of a vibrator being excited to vibrate.

FIG. 3 is a configuration diagram illustrating a configuration of a measurement system to measure a state of energy control in an electronic two-level system formed from a rare-earth element introduced into the vibrator.

FIG. 4 is a distribution diagram illustrating a measurement result of photoluminescence light from each bound exciton level of an electronic two-level system formed in the vibrator.

FIG. 5 is a perspective view illustrating a configuration of another solid-state quantum memory according to an embodiment of the present disclosure.

### DETAILED DESCRIPTION OF ILLUSTRATIVE EMBODIMENTS

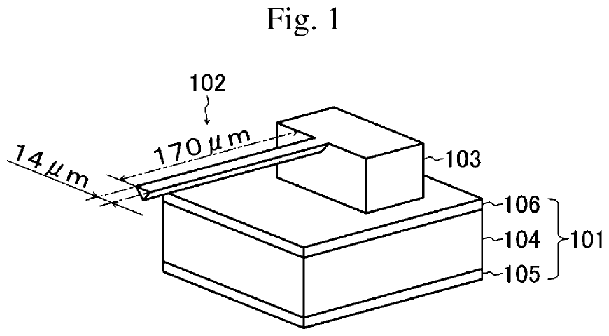

Hereinafter, a solid-state quantum memory according to an embodiment of the present disclosure will be described with reference to FIG. 1. The solid-state quantum memory includes a vibrator 102 supported in a displaceable (vibratable) manner on a substrate 101 and a vibration exciter that excites the vibrator 102 to vibrate. A rare-earth element is introduced into the vibrator 102 and the introduced rare-earth element forms an electronic two-level system in the vibrator 102. The rare-earth element is introduced into the vibrator 102 in an ionic state.

In this example, the vibrator 102 is supported on the substrate 101 by a support 103. The vibrator 102 is a cantilevered beam supported by the support 103. In this example, the support 103 and the vibrator 102 are integrally formed. The vibrator 102 is, for example, a triangular prism having an isosceles triangle base and having a length of 170 μm, a width of 14 μm, and a thickness of 7 μm. The isosceles triangle in the bottom surface of the vibrator 102, which is assumed to be a triangular prism, has a length of a base of 14 μm and a height of 7 μm.

The vibrator 102 can be formed from yttrium silicate (Y₂SiO₅), for example. The rare-earth element can be erbium (Er), for example. Er becomes an ion with an energy level having Kramers degeneracy. The rare-earth element is dispersed into the vibrator 102. The rare-earth element can also be configured to have a cluster of the rare-earth element to be dispersed into the vibrator 102. For example, the vibrator 102 (support 103) can be formed by three-dimensionally processing the Y₂SiO₅ material into which Er has been introduced, with a known focused ion beam (FIB).

The vibrator 102 which is assumed to be a prism can also have a stacked structure in which a layer of material forming the vibrator 102 and a layer of a rare-earth element are stacked in a thickness direction of the vibrator 102 by using a process such as molecular beam epitaxy, for example. For example, the vibrator 102 can be formed by alternately stacking a layer of material forming the vibrator 102 and a layer of a rare-earth element.

For example, the substrate 101 may be formed from a piezoelectric material to make the substrate 101 into a vibration exciter. For example, the substrate 101 can include a piezoelectric element 104 formed from a piezoelectric material, as well as a first electrode 105 and a second electrode 106 formed by sandwiching the piezoelectric element 104. By applying a vibration excitation signal (electrical signal) between the first electrode 105 and the second electrode 106 and oscillating the piezoelectric element 104, the vibrator 102 supported and fixed to the substrate 101 via the support 103 can be excited to vibrate. Additionally, by controlling the vibration excitation signal described above, the vibration excitation state of the vibrator 102 (dynamic strain generated in the vibrator 102) can be controlled.

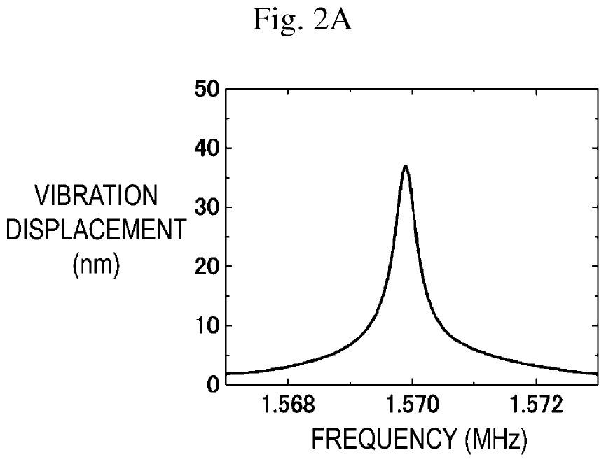

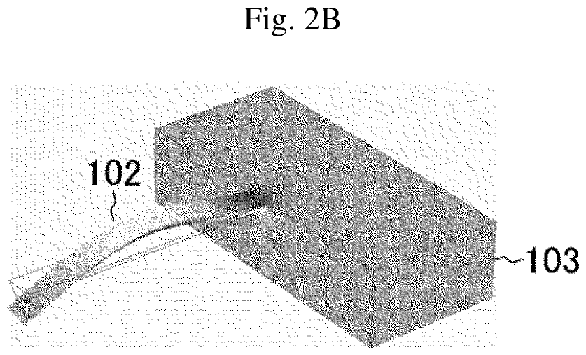

Next, with reference to FIGS. 2A and 2B, a resonance characteristic of the vibrator 102 in a secondary vibration mode and distribution of strain of the vibrator 102 being excited to vibrate with an electrical signal around 1.57 MHz will be described. First, as illustrated in FIG. 2A, it can be seen that the resonant frequency of the vibrator 102 is around 1.57 MHz. Second, as shown in the dynamic strain distribution of FIG. 2B, it can be seen that, in accordance with vibration excitation from the vibration exciter with the vibration excitation signal at the resonant frequency, a large strain (dynamic strain) has occurred in the vicinity of the center of the vibrator 102 having a beam structure.

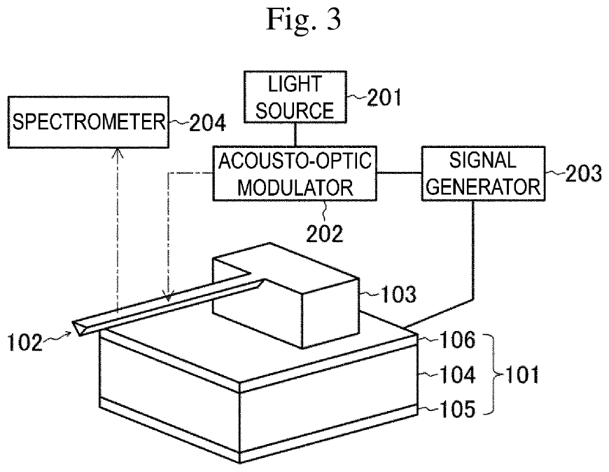

Next, energy control of the electronic level of the rare-earth element introduced into the vibrator 102 by the strain applied to the vibrator 102 will be described. This state of energy control of the electronic level can be measured by a photo luminescence excitation measurement. With reference to FIG. 3, a measurement system conducting the measurement will be described. The measurement system includes a light source 201, an acousto-optic modulator 202, a signal generator 203, and a spectrometer 204. First, a predetermined high frequency signal is applied from the signal generator 203 to an electrode of the substrate 101, which serves as the vibration exciter, and to the acousto-optic modulator 202.

Then, with the vibrator 102 being excited to vibrate by oscillating the vibration exciter, a continuous wave laser beam having a wavelength of 1536 nm emitted from the light source 201 including a laser is made into a pulsed laser beam by the acousto-optic modulator 202 and the vibrator 102 is irradiated with the pulsed laser beam. The wavelength of 1536 nm is the optical transition wavelength of Er. The irradiation with the pulsed laser beam results in photoluminescence (PL) light from each bound exciton level of an electronic two-level system (Er) formed in the vibrator 102. The PL light is measured by the spectrometer 204. In this measurement, by changing a relative phase between a pulse waveform of the laser beam that irradiates the vibrator 102 and vibration of the vibrator 102 being excited to vibrate, the energy of the bound exciton level with various strains being applied can be measured. Note that the measurement was performed in a cryogenic temperature and high vacuum (4 K, 1×10⁻⁴ Pa or less) environment for principle confirmation.

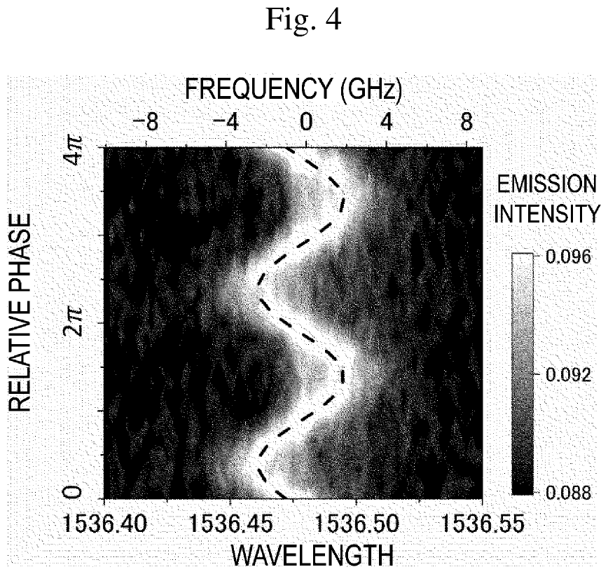

The measurement result of the PL light described above is shown in FIG. 4. As shown in FIG. 4, it is shown that, by applying a high frequency signal with a voltage of 5 V, energy control of approximately ±2 GHz is performed. This value is sufficiently greater than the typical inhomogeneous broadening of the electronic level of Er (approximately 1 GHz), implying that the coherence can be improved even in an environment without a magnetic field. Controlling preservation (controlling storage) of a quantum state in the electronic level with a solid-state quantum memory according to the embodiment has advantages, because no magnetic field is used, in the integration and low power consumption of the device compared to the case where a magnetic field is used. Additionally, according to the technique of the embodiment, it is also a feature that there is no decrease in coherence due to the instability of the magnetic field.

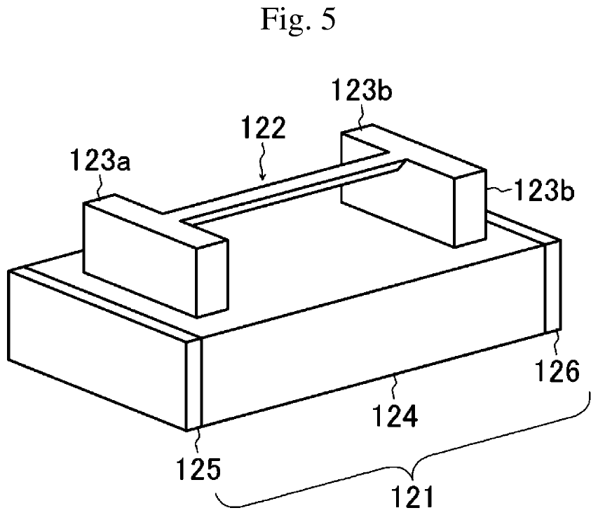

Incidentally, as illustrated in FIG. 5, the solid-state quantum memory according to an embodiment of the present disclosure can also include a vibrator 122 having a doubly supported beam structure. The solid-state quantum memory includes the vibrator 122 supported in a displaceable (vibratable) manner on a substrate 121 and a vibration exciter that excites the vibrator 122 to vibrate. A rare-earth element is introduced into the vibrator 122 and the introduced rare-earth element forms an electronic two-level system in the vibrator 122.

In this example, the vibrator 122 is supported on the substrate 121 by a first support 123a and a second support 123b. The vibrator 102 is a doubly supported beam having both ends supported and fixed to two supports, namely the first support 123a and the second support 123b. The vibrator 122 can be, for example, a triangular prism having an isosceles triangle base and having a length of 100 μm, a width of 20 μm, and a thickness of 10 μm. The isosceles triangle in the bottom surface of the vibrator 122, which is assumed to be a triangular prism, has a length of a base of 20 μm and a height of 10 μm. In this case as well, for example, a vibrator 122 (first support 123a and second support 123b) can be formed by three-dimensionally processing the Y₂SiO₅ material into which Er has been introduced, with a known focused ion beam.

Also, in this example as well, the substrate 121 may be formed from a piezoelectric material to make the substrate 121 into a vibration exciter. For example, the substrate 121 can include a piezoelectric element 124 formed from a piezoelectric material, as well as a first electrode 125 and a second electrode 126 formed by sandwiching the piezoelectric element 124. By applying a vibration excitation signal (electrical signal) between the first electrode 125 and the second electrode 126 and oscillating the piezoelectric element 124, the vibrator 122 supported and fixed to the substrate 121 via the first support 123a and the second support 123b can be excited to vibrate. Additionally, by controlling the vibration excitation signal described above, the vibration excitation state of the vibrator 122 (the dynamic strain generated in the vibrator 122) can be controlled.

In this structure, by using the piezoelectric element 124 that expands and contracts in an arrangement direction of the two electrodes, namely the first electrode 125 and the second electrode 126, in other words, an extending direction of the vibrator 122, which is assumed to have a doubly supported beam structure, allows the tensile stress applied to the vibrator 122 to be electrically controlled. Numerical calculation estimates that by applying an electrical signal (voltage signal) at a predetermined frequency between the first electrode 125 and the second electrode 126, when a displacement at both ends of the vibrator 122 becomes 100 nm, a stress of approximately 10 MPa is generated in the vibrator 122. This stress produces an energy change of approximately 4 GHz, and thus, by using the vibrator 122 having a doubly supported beam structure, precision control of resonance energy of the electronic two-level system formed from a rare-earth element included into the vibrator 122 is possible.

Note that, in the above description, Y₂SiO₅ was used as a base material of the vibrator, and Er was introduced into the base material; however, the present disclosure is not limited thereto. For the solid-state quantum memory, for example, Er having resonance in the telecom-wavelength band attracted the most attention; however, neodymium (example optical transition wavelength: 1064 nm), ytterbium, and the like can also be used as the rare-earth element. These also become ions with the energy level having Kramers degeneracy, and the similar effects as when Er is used are obtained.

Additionally, the measurement (photo luminescence excitation measurement) of state of energy control of the electronic level of the solid-state quantum memory according to an embodiment was performed in a cryogenic temperature and high vacuum (4 K, 1×10⁻⁴ Pa or less) environment for principle confirmation; however, operation of the solid-state quantum memory according to embodiments of the present disclosure is not limited to the specific environment.

Furthermore, in the embodiments described above, the vibrator has a triangular prism beam structure; however, the present disclosure is not limited thereto, and various other mechanical drive mechanisms (flat plate vibrator, surface acoustic wave, and the like) can be used in an analogous manner. Additionally, an example in which a piezoelectric element is used as a strain applying means is described; however, other strain applying means using electricity (electrostatic power), light (radiation pressure), heat (thermal expansion), and the like can be used in an analogous manner.

As described above, according to embodiments of the present disclosure, an electronic two-level system is formed from a rare-earth element introduced into a vibrator, and thus reduction in size and power consumption of the overall system to implement a quantum memory can be achieved.

Meanwhile, the present disclosure is not limited to the embodiments described above, and it will be obvious to those skilled in the art that various modifications and combinations can be implemented within the technical idea of the present disclosure.

### REFERENCE SIGNS LIST

101 Substrate
102 Vibrator
103 Support
104 Piezoelectric element
105 First electrode
106 Second electrode

1-6. (canceled)

7. A solid-state quantum memory comprising:
a vibrator supported in a displaceable manner on a substrate, the vibrator comprising a rare-earth element provided therein and having an electronic two-level system; and
a vibration exciter configured to excite the vibrator to vibrate.

8. The solid-state quantum memory according to claim 7, wherein the rare-earth element is introduced into the vibrator in an ionic state.

9. The solid-state quantum memory according to claim 8, wherein the rare-earth element includes an energy level having Kramers degeneracy in the ionic state.

10. The solid-state quantum memory according to claim 7, wherein the vibrator comprises a cantilevered beam structure.

11. The solid-state quantum memory according to claim 7, wherein the vibrator comprises a doubly supported beam structure.

12. The solid-state quantum memory according to claim 7, wherein the vibration exciter comprises a piezoelectric material.

13. A solid-state quantum memory comprising:
a substrate comprising a piezoelectric element provided between a first electrode and a second electrode;
a support provided on the substrate; and
a vibrator provided on the support, wherein the vibrator comprises a rare-earth element provided therein and has an electronic two-level system, and wherein the substrate is configured to receive an electrical signal and excite the vibrator to vibrate in response to the electrical signal.

14. The solid-state quantum memory according to claim 13, wherein the rare-earth element is introduced into the vibrator in an ionic state.

15. The solid-state quantum memory according to claim 14, wherein the rare-earth element includes an energy level having Kramers degeneracy in the ionic state.

16. The solid-state quantum memory according to claim 13, wherein the rare-earth element comprises erbium, neodynium, or ytterbium.

17. The solid-state quantum memory according to claim 13, wherein the vibrator comprises a cantilevered beam structure.

18. The solid-state quantum memory according to claim 13, wherein the support comprises a first support and a second support, and wherein a first end of the vibrator is provided on the first support and a second end of the vibrator is provided on the second support.

19. A method of forming a solid-state quantum memory, the method comprising:
dispersing a rare-earth element into a vibrator material to form a vibrator having an electronic two-level system; and
providing the vibrator on a substrate, wherein the substrate can excite the vibrator to vibrate.

20. The method according to claim 19, wherein the rare-earth element is dispersed into the vibrator in an ionic state.

21. The method according to claim 20, wherein the rare-earth element includes an energy level having Kramers degeneracy in the ionic state.

22. The method according to claim 19, wherein the vibrator is provided on a support on the substrate, and wherein the vibrator and the support are integrally formed.

23. The method according to claim 22, wherein the vibrator and the support have a cantilevered beam structure.

24. The method according to claim 19, wherein the vibrator is provided on a first support and a second support on the substrate, and wherein the vibrator, the first support, and the second support have a doubly supported beam structure.

25. The method according to claim 19, wherein the substrate comprises a piezoelectric element sandwiched between a first electrode and a second electrode.
